(19) United States
(12) Patent Application Publication
(10) Pub. No.: US 2024/0345314 A1
(43) Pub. Date: Oct. 17, 2024

(54) Dicing Lines for Photonics Circuits

(71) Applicant: LiGenTec SA, Ecublens (CH)

(72) Inventors: Davide Sacchetto, Ecublens (CH); Michael Zervas, Ecublens (CH); Gabriele Navickaite, Ecublens (CH)

(73) Assignee: LiGenTec SA, Ecublens (CH)

(21) Appl. No.: 18/682,905

(22) PCT Filed: Aug. 11, 2022
(86) PCT No.: PCT/EP2022/072530

§ 371 Date: Feb. 10, 2024

(30) Foreign Application Priority Data
Aug. 11, 2021 (GB) 2111524.1

(51) Int. Cl. G02B 6/12; H01L 21/78; H01L 23/00

(52) U.S. Cl. CPC G02B 6/12002; H01L 21/78; H01L 23/562

(57) ABSTRACT

A structure for relieving mechanical stress is presented. The structure comprises: a substrate; an indentation formed in the substrate; and a photonic layer formed on the substrate.

### TECHNICAL FIELD

This specification relates to fabrication of photonic integrated circuits.

### BACKGROUND

Photonic-grade silicon nitride films typically present large in-plane mechanical stress, limiting its use to small substrates and to a low density of photonic circuits. In order to fabricate photonic integrated circuits with a high density on any substrate size, an additional structure to relieve the in-plane mechanical stress is introduced in the substrate.

### SUMMARY

According to an aspect of the present invention, there is provided a structure for relieving mechanical stress. The structure comprises a substrate, an indentation formed in the substrate and a photonic layer formed on the substrate.

In some implementations, a depth of the indentation is equal to or larger than a thickness of the photonic layer. A width of the indentation is less than twice of the thickness of the photonic layer.

In some implementations, the photonic layer comprises a continuous layer with a first thickness and a discontinuous layer with a second thickness. The discontinuous layer is formed on the substrate and within the indentation and the continuous layer is formed on the discontinuous layer.

In some implementations, the continuous layer and the discontinuous layer comprise the same material.

In some implementations, the width of the indentation is twice the second thickness.

In some implementations, the first thickness is less than 0.5 micron.

In some implementations, the depth is equal to or larger than 1.2 microns and the width is equal to or larger than 0.9 microns.

In some implementations, a length of the indentation is equal to or larger than 20 microns. The length is defined in the direction normal to the directions of the depth and the width of the indentation.

In some implementations, a length of the indentation is equal to or larger than 100 microns. The length is defined in the direction normal to the directions of the depth and the width of the indentation.

In some implementations, there is provided a dicing line, comprising a first series of the structures defined hereinbefore. Each structure extends to a first length in a first direction. The plurality of the structures are aligned on a straight line extending in the first direction with a first period.

In some implementations, the dicing line comprises two or more of the first series of the structures. The straight lines along which the two or more the first series are aligned are parallel to each other. The two or more of the first series are staggered with respect to each other.

In some implementations, the dicing line further comprises a second plurality of the structures defined hereinbefore. Each structure extends to a second length in the first direction. The plurality of the structures are aligned on a straight line extending in the first direction with a second period.

In some implementations, the dicing line further comprises a second plurality of the structures defined hereinbefore. Each structure extends to a second length in a second direction orthogonal to the first direction. The plurality of the structures are aligned on a straight line extending in the first direction with a second period.

In some implementations, the first period and the second period are the same.

In some implementations, there is provided a wafer comprising a photonic integrated circuit. The photonic integrated circuit comprises the dicing line defined hereinbefore. The photonic integrated circuit is fabricated on the photonic layer, and the dicing line encloses an area with in the photonic layer.

In some implementations, the area enclosed by the dicing line is larger than 1 cm by 1 cm.

In some implementations, there is provided a wafer comprising a multi-level photonic integrated circuit. The wafer comprises a plurality of levels, each level containing a substrate and a photonic layer. A photonic integrated circuit is fabricated on the photonic layer of each level. The wafer further comprises the dicing line defined hereinbefore on at least one level. The dicing line encloses an area within the photonic layer in plan view.

In some implementations, the area enclosed by the dicing line is larger than 1 cm by 1 cm.

In some implementations, the dicing line enclosing the area is distributed on two or more levels.

### BRIEF DESCRIPTION OF THE DRAWINGS

Certain embodiments of the present invention will now be described, by way of examples, with reference to the accompanying drawings, in which:

FIG. 1 is a schematic of a structure for preventing fractures.

FIG. 2a shows a schematic depiction of a wafer on which photonic integrated circuits (PIC) are fabricated.

FIG. 2b is an exemplary image of the first and second dicing lines.

FIG. 2c shows a schematic illustration of series of indentations.

FIG. 3 shows an optical image of dicing lines and stopping a fracture.

FIG. 4 is a schematic of the structures for preventing fractures on a multi-level photonic circuit.

### DETAILED DESCRIPTION

An in-plane mechanical stress on a thin film leads to mechanical deformation.

When the stress exceeds a given value, cracks can form in the film, which deteriorates the functionality of the devices fabricated in the thin film. In silicon nitride (SiN) thin films with a thickness ranging from 400 nm to 800 nm, the typical residual stresses are on the order of 1 to 2 GPa, significantly smaller than the Young's modulus of the thin film silicon nitride by typically 2 orders of magnitude. However, any non-uniformities in the substrate or the silicon nitride film, or mishandling of the substrate can cause a local stress to exceed the limit dictated by the Young's modulus. This leads to a stress fracture or a crack in the thin film.

The generation or initiation of cracks or fractures is typically observed near the edges of a substrate due to a high concentration of the defects. A common countermeasure is to indent the substrate to stop the propagation of the fractures towards the middle of the substrate. However, this does not prevent the formation of the fractures when it is due to the presence of defects within the substrate and is limited to the use of small size substrates.

The present specification discloses indentations to reduce the generation of fractures, either by local defects or mishandling. The indentations are also to stop the propagation of the fracture and relieves the stress over the substrate.

In manufacturing photonic integrated circuits, dicing or wafer dicing is the process by which each photonic chip is separated from a wafer containing multiple integrated circuits.

The size of each chip may range from 0.1 mm to 40 mm and are typically rectangular-shaped. Between the functional parts of the photonic circuits, non-functional spacing is reserved for dicing lines or scribe lines, thereby defining the boundary of each chip. Along the dicing lines, each chip is separated from the wafer by various processes such as scribing and breaking, mechanical sawing or laser cutting.

The present specification discloses a dicing line including a plurality of indentations, demarcating the boundary of a photonic chip of any substrate size.

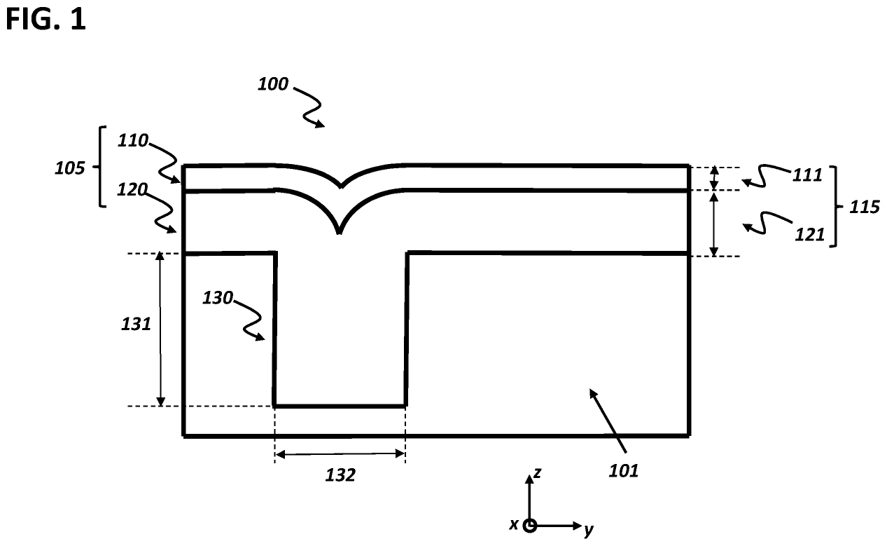

FIG. 1 is a schematic of a structure for preventing fractures.

The photonic integrated circuit is formed within a photonic layer 105 deposited on a substrate 101. For example, the substrate 101 may be silicon dioxide and the photonic layer 105 may be silicon nitride. Photonic structures, such as waveguides, can be patterned on a photonic layer 105.

A fracture prevention structure 100 is formed within the photonic integrated circuit. The fracture prevention structure 100 may be formed on a non-functional space of the photonic integrated circuit. The fracture prevention structure 100 may be formed after the photonic integrated circuits are fabricated. Alternatively, the fracture prevention structure 100 may be formed simultaneously as the photonic integrated circuit is fabricated.

The photonic layer 105 may comprise two layers: a first photonic layer 110, or a continuous layer 110 and a second photonic layer 120, or a discontinuous layer 120.

In some implementations, the first and second photonic layers 110, 120 may comprise the same material. In this case, the first photonic layer 110 and the second photonic layer 120 can be fabricated in a single deposition step. Alternatively, the first photonic layer 110 and the second photonic layer 120 can be fabricated in multiple deposition steps.

In some implementations, the first and second photonic layers 110, 120 may comprise different materials. For example, the first photonic layer 110 may have a different dopant concentration from the second photonic layer 120. For another example, the first photonic layer 110 may have a different microstructure than the second photonic layer 120.

The structure 100 includes an indentation 130, with a depth 131 in the z-direction, with a width 132 in the y-direction, with a length in the x-direction. The depth is defined to be in the direction of the thickness of the substrate 101 or normal to the plane of the substrate 101. The width is defined to be parallel to the plane of the substrate 101. The x-direction and the y-direction refer to any two orthogonal directions within the plane of the substrate 101.

The second photonic layer 120, or the discontinuous layer 120, is deposited to fill the void formed by the indentation 130.

In some implementations, the first photonic layer 110, or the continuous layer 110, is deposited on the second photonic layer 130.

In some implementations, when the first and second photonic layers 110, 120 are made of the same material, the first and second photonic layers 110, 120 can be deposited in one deposition step.

In some implementations, the indentation 130 can be in the form of an elongated channel, which extends in the x-direction with a constant width in the y-direction.

As shown in FIG. 1, the structure of the photonic layer 105, 110, 120 can be warped or distorted due to the presence of the indentation 130 in the yz-plane. The propagation of a crack or a fracture stops when it reaches the position of the indentation 130. For example, when a crack or a fracture starts on the left-hand side of the indentation 130, the propagation of the crack towards the right, in the positive y-direction, is stopped by the fracture prevention structure 100.

The first photonic layer 110 has a first thickness 11 and the second photonic layer 120 has a second thickness 121. The thickness of the photonic layer 105 is the sum of the first thickness 111 and the second thickness 121.

The thickness of the first photonic layer 110 and the thickness of the second photonic layer 120 here refer to the thickness at a position on xy-plane on the substrate substantially far away from the position of the indentation 130, where the photonic layers 110, 120 are uniformly formed.

The depth 131 and the width 132 of the indentation 130 can be determined to maximise the efficacy of stopping the propagation of the crack and to minimise the in-plane mechanical stress of the photonic layer 105.

In particular, the depth 131 of the indentations 130 in the substrate 101 is set to be equal to or larger than the thickness of the photonic layer 105, or the sum of the first thickness 111 and the second thickness 121. The width 132 of the indentations 130 in the substrate 101 is set to be less than twice of the thickness of the photonic layer 105, or the sum of the first thickness 111 and the second thickness 121.

In some implementations, the width 132 of the indentation 130 is set to be twice the second thickness 121 to produce sufficient stress discontinuity. If we refer to the thickness of the first photonic layer 110, or the first thickness 111 as et and the thickness of the photonic layer 105, a total thickness 115, as ft, this condition is expressed as:

wi=2×(ft−ct).

When this condition is met, the stress on the second photonic layer 120 can be disregarded and the total in-plane mechanical stress is reduced to that equivalent to the first layer 110.

When the first and second photonic layers 110, 120 are the same material, the first and second thickness 111, 121 can be estimated from the above relation. When the first and second photonic layers no, 120 are the same material, the first and second photonic layers no, 120 may differ from each other in terms of fundamental properties, such as mechanical stress field. In this case, the stress field in the first photonic layer no is regarded as more tensile and in-plane whereas the stress field in the second photonic layer 120 is interrupted by the indentation 130, thereby directed out of plane. For example, when the width 132 of the indentation 130 is 900 nm for a photonic layer 105 of 600 nm thickness, the first thickness 111 of the continuous layer 110 is estimaged to be 150 nm.

In some implementations, the width 132 of the indentation 130 are determined on the assumption that the first thickness 111 is equal to or less than 500 nm. This is because in case of stoichiometric silicon nitride, fracture generation is negligible when the first thickness 111, or the thickness of the continuous film 110 is less than 500 nm. In this case, the width 132 satisfies the following condition:

wi≥2×(ft−500 nm).

For example, a minimum width 132 of the indentation 130 of 600 nm is required for a photonic layer 105 of 800 nm thickness. This is counterintuitive with respect to other indentation schemes found in the state of the art, for which the wi limit was assumed to be for ct=0 nm or twice the film thickness.

For another example, for a photonic layer 105 with a thickness 1 micron, the width 132 can be 1.5 micron.

In some implementations, the width 132 of the indentations 130 in the substrate 101 is at least 50% wider than the thickness of the photonic layer 105, or the sum of the first thickness 111 and the second thickness 121. In this case, the following condition is satisfied:

ft>4×ct.

In some implementations, the photonic layer 105, such as silicon nitride, is deposited on both front side and backside of substrate 101. For example, this may be achieved via low-pressure chemical vapour deposition techniques.

This specification provides a square shaped cross-section of the indentation 130. However, in some implementations, the indentations 130 may have an adaptive shape, which can be modified from the square cross-section with a numerical simulation calculating the stress-field of the specific designs to be patterned on a substrate. This allows for an optimized uniform stress-field distribution allowing for high-quality high-yield manufacturing of photonic circuits.

The fracture prevention structure 100 as described above can also be provided on the back surface of the substrate 101 and dicing lines as will be described later may be formed on the front side and backside of the substrate. This enables mechanical substrate handling without damaging photonic structure fabricated on the photonic layer 105 on the front side and the back side of the substrate 101.

In photonic integrated circuit (PIC) manufacturing, mechanical tools such as pinsettes are used for lifting the substrate 101 and this often causes the generation of crack and delamination or removal of the photonic layer 105 such as silicon nitride deposited on the back side of the substrate 101. By preparing the fracture prevention structure 100 and dicing lines from the fracture prevention structure 100, the damages caused in mechanical handling can be mitigated.

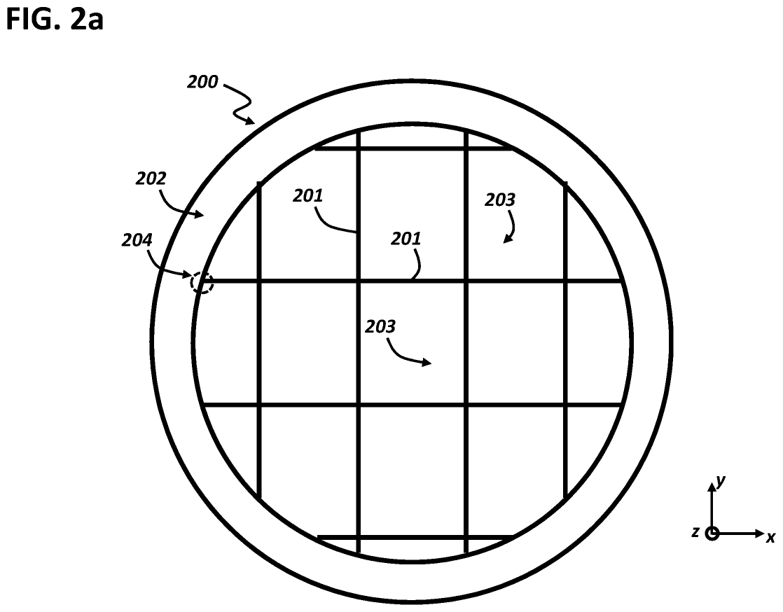

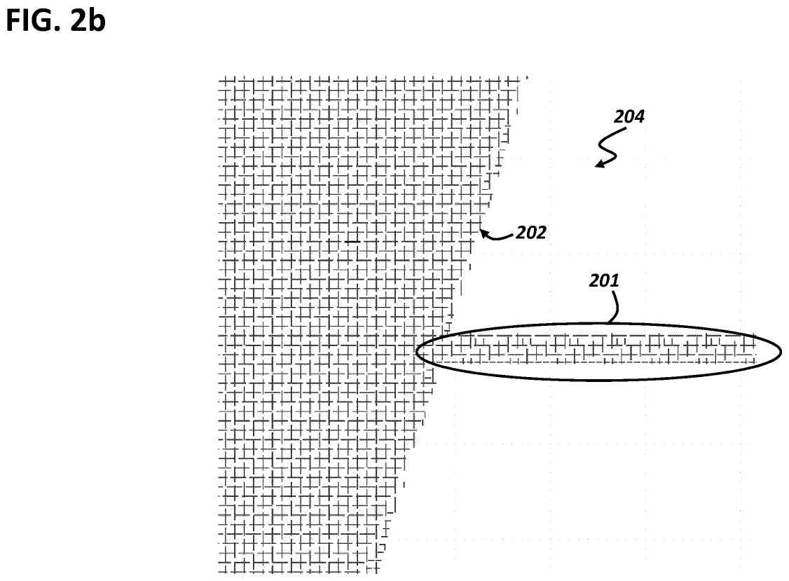

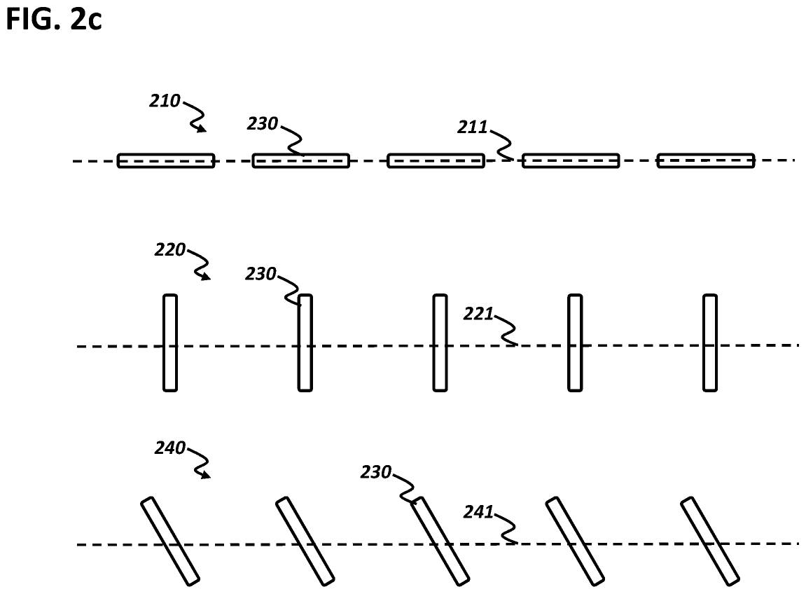

FIGS. 2a and 2b are schematics for fracture prevention structures used as dicing lines on a substrate.

FIG. 2a shows a schematic depiction of a wafer 200 on which photonic integrated circuits (PIC) are fabricated. For example, the wafer 200 includes the substrate 101 and the photonic layer 105 as discussed in FIG. 1.

The wafer 200 is divided into a plurality of PIC area enclosures 203 demarcated by a first dicing line 201. A second dicing line 202 circumvents the wafer 200.

In some implementations, the first dicing line 201 can be configured to stop or prevent fracture generation in addition to stopping the propagation of fracture.

In some implementations, the first dicing line 201 can be configured to relieve in-plane stress such that the generation of crack or fracture from defective location, such as defects on the substrate 100 or on the wafer 200 on the substrate is prevented.

In some implementations, the second dicing lines 202 can be configured to stop the propagation of fracture generated from the edge of the wafer 200.

FIG. 2b is an exemplary image of the first and second dicing lines 201, 202.

FIG. 2b is a magnified illustration of the region labelled 204 in FIG. 2a, where the first dicing line 201 and the second dicing line 202 intersect.

The first and second dicing lines 201, 202 comprise a plurality of the fracture prevention structure 100 described in FIG. 1. FIG. 2b shows that the first and second dicing lines 201, 202 comprise a plurality of strips or the straight lines. Each of the strips or the straight lines aligned with respect to each other represents an elongated indentation 130 of the fracture prevention structure 100. The length of each strip corresponds to the extent of the indentation 130 in the x-direction in FIG. 1. Since each strip is elongated such that the length in the x-direction is much larger than the width 132, each fracture prevention structure 100 is represented as a short strip. For example, the length of the indentation 130, in the x-direction, may range from 10 to 200 microns, typically 40 microns. The indentations 130 may be aligned in length direction with a set period. The period may be larger than 1.5 times the length of the indentation 130.

For convenience, each fracture prevention structure 100 forming the first and second dicing lines 201, 202 will be interchangeably referred to as indentations 130, 230 in the sense that the lateral dimension of each fracture prevention structure 100 is defined by the geometry of the indentations 130, 230. However, it is understood that the indentation 130, 230 created within the substrate 101 is covered with the photonic layer 105 and only the warped part or the distorted part of the photonic layer 105 over the indentation 130, 230 may be imaged to be visible.

The first dicing line 201 and the second dicing line 202 include a plurality of indentations 130, 230 with a repeated pattern.

In some implementations, two groups of the indentations 130, 230 each elongated in two orthogonal directions may be included in each of the first dicing line 201 and the second dicing line 202. For example, FIG. 2b shows that the indentations 130 in x-direction and the indentations 130, 230 direction in y-direction are included in both the first dicing line 201 and the second dicing line 202, when x- and y-directions are defined as in FIG. 2a.

Since the propagation of the fracture is mostly linear with slow variation of directions, covering at least two directions cover cracks or fractures propagating in all angles. However, the number of directions is not limited two and more than two orthogonal angles can be included in the first and second dicing lines 201, 202. For convenience, in this specification, the examples of the dicing lines 201, 202 will include indentations directed in two orthogonal directions and these will be referred to normal and parallel indentations.

In this specification, a periodic repetition of indentations 130, 230 of the same length, the same depth 131, the same width 312 and the same direction will be referred to as a series of indentations 130, 230.

FIG. 2c shows a schematic illustration of series of indentations.

A series of parallel indentation 210 includes a plurality of indentations 130, 230 aligned lengthwise along a single line 211. The plurality of indentations 130, 230 are aligned along the single line 211 in a periodic fashion. In this specification, such series of indentations will be referred to as a series of parallel indentations, in that each indentation is parallel to the single line 211.

A series of normal indentation 220 includes a plurality of indentations 130, 230 aligned normal to a single line 221. The plurality of indentations 130, 230 are aligned along the single line 211 in a periodic fashion but in a way that each indentation 130, 230 is positioned perpendicular to or normal to the single line 221. In this specification, such series of indentations will be referred to as a series of normal indentations, in that each indentation is normal to the single line 221.

The angle of the indentations 130, 230 within a series is not limited to either normal direction or parallel direction along the central line 211, 221.

For example, FIG. 2c shows a series of indentations 240 including a plurality of indentations 130, 230 aligned along a single line 241 and angled with respect to the single line 241 at a 60 degrees angle. However, the angle is not limited to 60 degrees angle. Any angle between 0 to 90 degrees can be used.

The first and second dicing lines 201, 202 can include a plurality of series of indentations such that the single lines 211, 221, 241 along which the indentations are parallel to each other. In some implementations, the direction of the second dicing line 202 may coincide with the single lines 211, 221, 241.

The first and second dicing lines 201, 202 can include series of indentations 130, 230 with different angles of indentations 130, 230. For example, the second dicing line 202 may include one series of normal indentations 220, one series of parallel indentations 210 and a series of indentations angled at 45 degrees angle.

The number of angles of the indentations 130, 230 within the first and second dicing lines 201, 202 is not limited two or three.

The indentations 130, 230 are arranged within the first and second dicing lines 201, 202 such that the propagation of cracks is stopped even when the advancement of cracks is curved or when the crack changes directions.

Unless otherwise noted, within a series of parallel or normal indentations, the length of each indentation 130, 230, in the x-direction in FIG. 1, and the period are kept constant throughout the series. However, the implementation is not limited to this configuration. Within a series of indentations, 130, 230, the length of the indentations 130, 230 and/or the period can vary if necessary.

In some implementations, the first and second dicing lines 201, 202 may each include two or more series of parallel indentations 130, 230 with different lengths of the indentations 130, 230.

In some implementations, the first and second dicing lines 201, 202 may each include two or more series of indentations 130 with different widths of the indentations 130, 230.

As shown in FIG. 2b, the second dicing line 202 contains a larger number of indentations 101 than the first dicing line 201.

In some implementations, the width of the first dicing line 201 and/or the second dicing line 202 is at least 20 microns and contains at least one series of normal indentations 130 and at least one series of parallel indentations 130. In case the photonic layer 105 is silicon nitride, it was found experimentally that the propagation of the cracks is highly likely to be stopped with this configuration.

In some implementations, the width of the first dicing line 201 and/or the second dicing line 202 is at least 100 microns and contains at least three series of normal indentations 130 and at least three parallel indentations 130. In case of the photonic layer 105 of silicon nitride, it was found experimentally that the generation of cracks from the defects, which can be initiated by mishandling, is likely to be prevented with this configuration.

In some implementations, the indentations 130 in each series of the first dicing line 201 and/or the second dicing line 202 can be staggered such that throughout the extent of the first dicing line 201 and/or the second dicing line 202, at least one indentation 130 blocks the propagation of cracks.

In some implementations, the first indentation line 201 contains at least two series of parallel indentations 130, 230, where the indentations 130, 230 in each series are aligned lengthwise.

In some implementations, the first indentation line 201 contains at least two series of parallel indentations 130, 230 where the indentations 130, 230 in each series are aligned lengthwise and the at least two series of parallel indentations 130 are staggered such that crack propagation in any direction is covered throughout the entire length of the first indentation line 201. Here, the two series of parallel indentations 130, 230 can have the same period and indentations 130, 230 of identical dimensions. The positions of the indentations 130, 230 in a first series of parallel indentations 130, 230 can be translationally shifted with respect to a second series of parallel indentations. In this case, the gap between two adjacent indentations 130, 230 the first series can be overlapped by the one of the indentations 130, 230 of the second series such that the propagation of the crack through the gap of the first series is stopped by the indentation 130, 230 of the second series.

In some implementations, the first indentation line 201 contains at least two series of parallel indentations 130, 230 and at least one series of normal indentations 130, 230, where the two series of parallel indentations 130, 230 are staggered. In this case, the period of the two series of parallel indentations 130, 230 can be the same and the period of the series of normal indentations can be different from that of the series of parallel indentations.

In some implementations, the width of the first dicing line 201 is smaller than the second dicing line 202.

In some implementations, the width of the first dicing line 201 is at least 20 microns and the first dicing line 201 contains at least two series of normal indentations 130 and at least two series of parallel indentations 130 and the width of the second dicing line 202 is at least 100 microns and the second dicing line 202 contains at least three series of normal and parallel indentations.

The first dicing line 201 can include as many elongated indentations 130 as possible. In other words, the first dicing line 201 can be laid out by placing indentations 130 to be as thick as possible within the non-functional area of the photonic integrated circuit.

It was found experimentally that when the first dicing lines 201 with 20 micron width containing three series of normal indentations 130 and three series of parallel indentations 130 was provided to the wafer 200 such that an area within the substrate 101 as large as 4 cm×4 cm in size is enclosed, no cracks were generated within that area.

It was also found experimentally when the first dicing lines 201 with 20 micron width containing three series of normal indentations 130 and three series of parallel indentations 130 was provided to the wafer 200 of 10 cm×10 cm and the wafer was diced along the first dicing lines 201, no crack was generated in the process.

The indentation pattern forming the dicing lines 201, 202 consists of a local thickness discontinuity of the substrate 101. As the total strain of the substrate 101 is discontinued, the probability of a fracture being generated inside the area 203 enclosed by the dicing lines 201, 202 is minimized, allowing for the fabrication of high density so photonic circuits inside the enclosure.

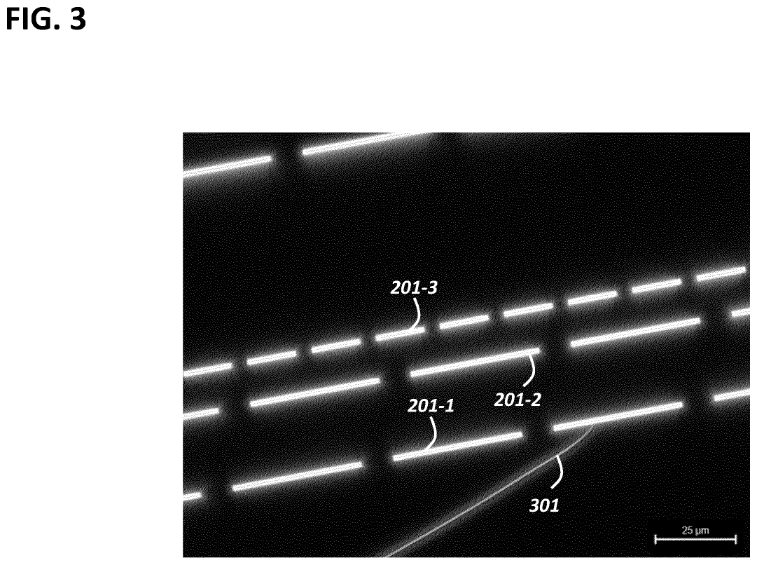

FIG. 3 shows an optical image of dicing lines stopping a fracture.

A PIC enclosure area 203 shown in FIG. 2a is demarcated by a first dicing line 201 containing three series of parallel indentations 130, 230, a first series 201-1, a second series 201-2 and a third series 201-3. Each indentation 130, 230 of the first series 201-1 and the second series 202-2 have the same length. The indentations 130, 230 of the third series 201-3 are shorter that those of the first and second series 201-1, 201-2. The period of the third series 201-3 is smaller than that of the first and second series 201-1, 201-2. In all three series of parallel indentations, 201-1, 201-2, 201-3, the indentations 130, 230 are aligned lengthwise such that each series forms a straight line. The lines formed by the three series of parallel indentations 201-1, 201-2, 201-3, are parallel to each other. The first series 201-1 and the second series 201-2 are parallel to each other but staggered in the length direction, such that the gap between two adjacent indentations in the first series 201-1 overlaps with one of the indentations 130, 230 of the second series 201-2, and vice versa. The third series 201-3 is placed on the opposite side from the first series 201-1 with respect to the second series 201-2.

FIG. 3 shows that the propagation of the fracture 301 is blocked by one of the indentations 130, 230 of the first series 201-1.

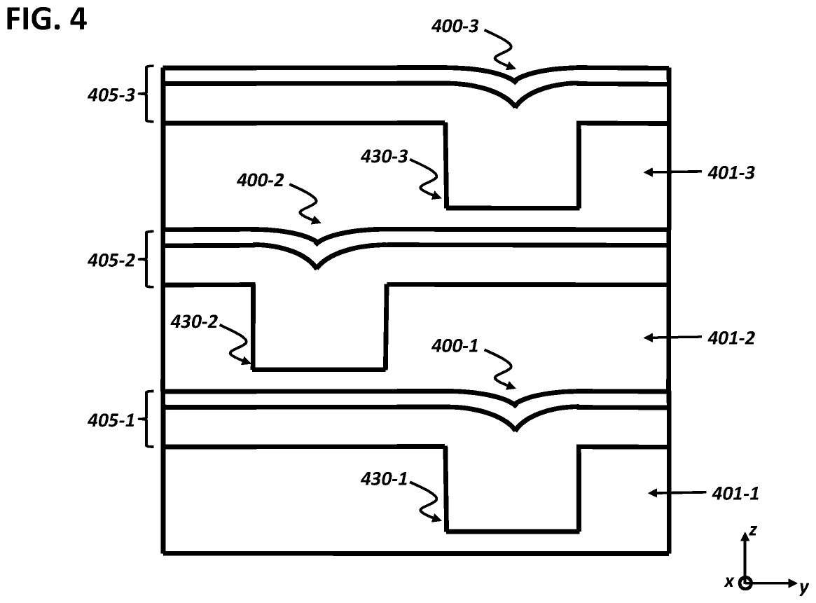

FIG. 4 is a schematic of the structures for preventing fractures on a multi-level photonic circuit.

The structure 400 includes three fracture prevention structures 400-1, 400-2, 400-3. Each fracture prevention structures is as described in FIG. 1.

The photonic integrated circuit is formed on three photonic layers, 405-1, 405-2, 405-3 deposited on respective substrates 401-1, 401-2, 401-3.

A bottom photonic layer 405-1 is deposited on a bottom substrate 401-1. A first fracture prevention structure 400-1 can be formed as described in FIG. 1 on the bottom photonic layer 405-1 and the bottom substrate 401-1.

A middle substrate 401-2 is deposited on the bottom photonic layer 405-1 after a photonic circuit and the first fracture prevention structure 400-1 are formed and a middle photonic layer 405-2 is deposited on the middle substrate 401-2. A second fracture prevention structure 400-2 can be formed as described in FIG. 1 on the middle photonic layer 405-2 and the middle substrate 401-2. The thickness of the middle substrate 401-2 is such that the optical modes within the bottom photonic layer 405-1 is not perturbed by the photonic circuits on the bottom photonic layer 405-1 and the bottom substrate 401-1.

A top substrate 401-3 is deposited on the middle photonic layer 405-2 and a top photonic layer 405-3 is deposited on the top substrate 401-3. A third fracture prevention structure 400-2 can be formed as described in FIG. 1 on the top photonic layer 405-3 and the top substrate 401-3. The thickness of the top substrate 401-3 is such that the optical modes within the middle photonic layer 405-2 is not perturbed.

In the example of FIG. 4, three photonic layers 405-1, 405-2, 405-3 are on top of each other, but the number of photonic layers is not limited to three and any number of photonic integrated circuits can be implemented. The fracture prevention structure 100, 400-1, 400-2, 400-3 disclosed in this specification, is highly modular.

The lateral position of the fracture prevention structures 400-1, 400-2, 400-3, in the xy-plane, can be determined according to the photonic integrated circuits included in each of the photonic layers 405-1, 405-2, 405-3.

The embodiments of the invention shown in the drawings and described hereinbefore are exemplary embodiments only and are not intended to limit the scope of the invention, which is defined by the claims hereafter. It is intended that any combination of non-mutually exclusive features described herein are within the scope of the present invention.

1. A structure for relieving mechanical stress, comprising:
a substrate;
an indentation formed in the substrate; and
a photonic layer formed on the substrate.

2. The structure of claim 1,
wherein a depth of the indentation is equal to or larger than a thickness of the photonic layer, and
wherein a width of the indentation is less than twice of the thickness of the photonic layer.

3. The structure of claim 1,
wherein the photonic layer comprises:
a continuous layer with a first thickness; and
a discontinuous layer with a second thickness,
wherein the discontinuous layer is formed on the substrate and within the indentation, and
wherein the continuous layer is formed on the discontinuous layer.

4. The structure of claim 3,
wherein the continuous layer and the discontinuous layer comprise the same material.

5. The structure of claim 3,
wherein the width of the indentation is twice the second thickness.

6. The structure of claim 3,
wherein the first thickness is less than 0.5 micron.

7. The structure of claim 1,
wherein the depth is equal to or larger than 1.2 microns and the width is equal to or larger than 0.9 microns.

8. The structure of claim 1,
wherein a length of the indentation is equal to or larger than 20 microns,
wherein the length is defined in the direction normal to the directions of the depth and the width of the indentation.

9. The structure of claim 1,
wherein a length of the indentation is equal to or larger than 100 microns,
wherein the length is defined in the direction normal to the directions of the depth and the width of the indentation.

10. A dicing line, comprising:
a first series of the structures according to claim 1,
wherein each structure extends to a first length in a first direction, and
wherein the plurality of the structures are aligned on a straight line extending in the first direction with a first period.

11. The dicing line of claim 10, comprising:
two or more of the first series of the structures,
wherein the straight lines along which the two or more the first series are aligned are parallel to each other, and
wherein the two or more of the first series are staggered with respect to each other.

12. The dicing line of claim 10, further comprising:
a second plurality of the structures according to claim 1,
wherein each structure extends to a second length in the first direction, and
wherein the plurality of the structures are aligned on a straight line extending in the first direction with a second period.

13. The dicing line of claim 10, further comprising:
a second plurality of the structures according to claim 1,
wherein each structure extends to a second length in a second direction orthogonal to the first direction, and
wherein the plurality of the structures are aligned on a straight line extending in the first direction with a second period.

14. The dicing line of claim 13,
wherein the first period and the second period are the same.

15. A wafer comprising a photonic integrated circuit, the wafer comprising:
the dicing line of claim 10,
wherein the photonic integrated circuit is fabricated on the photonic layer, and
wherein the dicing line encloses an area within the photonic layer.

16. The wafer of claim 15,
wherein the area enclosed by the dicing line is larger than 1 cm by 1 cm.

17. A wafer comprising a multi-level photonic integrated circuit, the wafer comprising:
a plurality of levels, each level containing a substrate and a photonic layer, wherein a photonic integrated circuit is fabricated on the photonic layer of each level; and
the dicing line of claim 10 on at least one level,
wherein the dicing line encloses an area within the photonic layer in-plane view.

18. The wafer of claim 17,
wherein the area enclosed by the dicing line is larger than 1 cm by 1 cm.

19. The wafer of claim 17,
wherein the dicing line enclosing the area is distributed on two or more levels.
